(19) United States
(12) Patent Application Publication
(10) Pub. No.: US 2021/0200084 A1
(43) Pub. Date: Jul. 1, 2021

(54) POLYMERS AND PHOTORESIST COMPOSITIONS

(71) Applicant: ROHM AND HAAS ELECTRONIC MATERIALS LLC, Marlborough, MA (US)

(72) Inventors: Jong Keun Park, Shrewsbury, MA (US); Emad Aqad, Northborough, MA (US); Yang Song, Framingham, MA (US); Chunyi Wu, Shrewsbury, MA (US); Colin Liu, Shrewsbury, MA (US); Mingqi Li, Shrewsbury, MA (US)

(21) Appl. No.: 16/731,666

(22) Filed: Dec. 31, 2019

(51) Int. Cl. G03F 7/038; C08F 212/14; G03F 7/039

(52) U.S. Cl. CPC G03F 7/038; G03F 7/162; G03F 7/039; C08F 212/24

(57) ABSTRACT

A polymer comprising a first repeating unit derived from a monomer comprising a hydroxy-aryl group; a second repeating unit derived from a monomer comprising a hydroxy-aryl group protected with an acetal or ketal group; a third repeating unit derived from a (meth)acrylate monomer comprising a cycloaliphatic group; and a fourth repeating unit derived from a monomer comprising an acid-sensitive group, wherein the first, the second, the third, and the fourth repeating units are different from each other.

### FIELD

The present invention relates to photoresist compositions useful for photolithography and to polymers having use in such compositions. Specifically, the invention relates to chemically amplified photoresist compositions that are useful in forming thick photoresist layers and to polymers having use in such compositions.

### BACKGROUND

The Integrated Circuit (IC) industry has achieved the low cost of a bit by going towards smaller geometries. However, further miniaturization of the critical dimensions could not be realized by current lithographic techniques with similarly low production cost. NAND flash manufacturers have been looking into techniques for stacking multiple layers of memory cells to achieve greater storage capacity while still maintaining lower manufacturing cost per bit. Miniaturization of critical features while keeping the manufacturing cost low, has led to the development of stacked 3D structures for NAND applications. Such 3D NAND devices are denser, faster, and less expensive than the traditional 2D planar NAND devices.

The 3D NAND architecture comprises vertical channel and vertical gate architectures, and the stepped structure (known as “staircase”) is used to form an electrical connection between memory cells and bit lines or word lines. In constructing 3D NAND flash memories, manufacturers increase the number of stairs using a thick resist that allows for multiple trimming and etching cycles used for staircase formation Maintaining good feature profile on each step is challenging since subsequent trimming-etching variations on critical dimension (CD) will be accumulated step by step and across the wafer.

The process of “staircase” formation uses a single mask exposure of a thick KrF photoresist (at a wavelength of 248 nm) to etch stairs controlled by a precise resist trim. The trimming step controls the location of the steps such that they align with the contact mask, and so must be tightly controlled to minimize misalignment. As the 3D-NAND architectures are pushed from 64 vertical layers, to 96 layers, 128 layers and beyond, thicker resist coatings (i.e., thicker resist films) are required. The use of thicker resist films in KrF lithography for printing micrometer scale features is associated with unique technical challenges. Patterning a thick resist film requires sufficient film transmittance at exposure wavelength (248 nm) to allow incident radiation to reach the bottom of the film. Moreover, thick resist films used in 3D NAND applications are subject to a series of vertical and horizontal “Pull-Back” etch steps. Exposing thick resist film to etch treatments can affect film structure uniformity and can lead to the formation of rough film surfaces and the formation of undesired voids in the film. Suitable thick resist films should be able to maintain film physical structure after each etch treatment.

Therefore, there is a continuing need for polymers and coating compositions that could be suitable for thick photoresist films, which have improved transmittance at exposure wavelength, excellent retention of properties after thickness trimming and etching, and increased photospeed.

### SUMMARY

An embodiment provides a polymer comprising a first repeating unit derived from a monomer comprising a hydroxy-aryl group; a second repeating unit derived from a monomer comprising a hydroxy-aryl group protected with an acetal or ketal group; a third repeating unit derived from a (meth)acrylate monomer comprising a cycloaliphatic group; and a fourth repeating unit derived from a monomer comprising an acid-sensitive group, wherein the first, the second, the third, and the fourth repeating units are different from each other.

Another embodiment provides a photoresist composition comprising the polymer, a photoacid generator, and a solvent.

Still another embodiment provides a method of forming a pattern comprising applying a layer of the photoresist composition on a substrate; drying the applied photoresist composition to form a photoresist composition layer; exposing the photoresist composition layer to activating radiation; heating the exposed photoresist composition layer; and developing the exposed composition layer to form a resist pattern.

### BRIEF DESCRIPTION OF THE DRAWINGS

The above and other aspects of the present invention will become more apparent by describing in detail exemplary embodiments thereof with reference to the attached drawings, in which:

FIGS. 1A to 1K are representative diagrams schematically showing steps of a method of forming a staircase pattern in accordance with an embodiment of the present invention.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments only and is not intended to be limiting. As used herein, the singular forms “a,” “an,” and “the” are intended to include the plural forms as well, unless the context clearly indicates otherwise. It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments. It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art of the disclosed subject matter. It will be further understood that terms, such as those defined in commonly used dictionaries, should be interpreted as having a meaning that is consistent with their meaning in the context of the relevant art and the present invention, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents and/or comprising one or more heteroatoms instead of carbon where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O”; “carboxylic acid group” refers to a group having the formula “—C(═O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenylene group” refers to an alkenyl group having a valence of two; “cycloalkenyl group” refers to a non-aromatic cyclic divalent hydrocarbon group having at least three carbon atoms, with at least one carbon-carbon double bond; “aryl group” refers to a monovalent aromatic monocyclic or polycyclic ring system, and may include a group with an aromatic ring fused to at least one cycloalkyl or heterocycloalkyl ring; “arylene group” refers to an aryl group having a valence of two; “alkylaryl group” refers to an aryl group that has been substituted with an alkyl group; “arylalkyl group” refers to an alkyl group that has been substituted with an aryl group. The prefix “hetero” means that the compound or group includes at least one member that is a heteroatom (e.g., 1, 2, or 3 heteroatom(s)) instead of a carbon atom, wherein the heteroatom(s) is each independently N, O, S, Si, or P. The term “heteroalkyl group” refers to an alkyl group having 1-3 heteroatoms instead of carbon; “heterocycloalkyl group” refers to a cycloalkyl group having 1-3 heteroatoms as ring members instead of carbon; “heterocycloalkylene group” refers to a heterocycloalkyl group having a valence of two; “heteroaryl group” refers to an aromatic group having 1-4 heteroatoms as ring members instead of carbon; “aryloxy group” refers to “aryl-O”; and “arylthio group” refers to “aryl-S—”. The prefix “halo” means a group including one more of a fluoro, chloro, bromo, or iodo substituent instead of a hydrogen atom. A combination of halo groups (e.g., bromo and fluoro), or only fluoro groups may be present. The term “(meth)acrylate” is inclusive of both methacrylate and acrylate, the term “(meth)allyl” is inclusive of both methallyl and allyl, and the term “(meth)acrylamide” is inclusive of both methacrylamide and acrylamide.

Unless otherwise specified, “substituted” means that at least one hydrogen atom on the group is replaced with another group, provided that the designated atom's normal valence is not exceeded. When the substituent is oxo (i.e., ═O), then two hydrogens on the atom are replaced. Combinations of substituents or variables are permissible. Exemplary groups that may be present on a “substituted” position include, but are not limited to, nitro (—NO₂), cyano (—CN), hydroxy (—OH), oxo (═O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof, C₂₋₆ alkyl ester (—C(═O)O-alkyl or —OC(═O)-alkyl), C₇₋₁₃ aryl ester (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen (e.g., fluorine, chlorine, bromine), thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ heteroalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group. When a group is substituted, each atom in the group may be independently substituted or unsubstituted, provided that at least one atom is substituted. For example, a substituted C₃ alkyl group may be a group of the formula —CH₂C(═O)CH₃ or a group of the formula —CH₂C(═O)CH₍₃₋ₙ₎Yₙ, where each Y is independently a substituted or unsubstituted C₃₋₁₀ heterocycloalkyl and n is 1 or 2.

As noted above, there is a need for polymers and photoresist compositions having good transmittance at exposure wavelength, excellent retention of mechano-physical properties after multiple thickness trimming and etch treatments, and increased photospeed.

Disclosed herein is a polymer for a photoresist composition designed for thick film patterning. The polymer includes at least four different repeating units, which include a first repeating unit derived from a monomer comprising a hydroxy-aryl group, such as hydroxystyrene; a second repeating unit derived from a monomer comprising a hydroxy-aryl group protected with an acetal or ketal group, which can provide improved photospeed and lithographic performance; a third repeating unit derived from a (meth)acrylate monomer comprising a cycloaliphatic (monocyclic or polycyclic) group, which can provide improved etch resistance and light transparency at exposure wavelengths; and a fourth repeating unit derived from a monomer comprising an acid-sensitive group such as a tertiary alkyl ester or an acetal group, which hydrolyzes upon the action of an acid. The disclosed polymer can provide improved etch performance, less development residue, and higher transmittance at 248 nm wavelength when used in a photoresist composition. The use of at least four different and particular types of repeating units in the polymer, for example as a tetrapolymer or higher order polymer, can provide significantly improved performance compared to the corresponding polymers that do not include each of the different repeating units disclosed herein.

As used herein, the term “polymer” refers to both polymers and copolymers. Thus, the disclosed polymeric compound that includes at least four different repeating units can be referred to as a polymer or a copolymer.

It is to be understood that “different repeating units” means the repeating units have different structures from each other.

The first repeating unit is derived from a monomer comprising a hydroxy-aryl group. In an embodiment, the polymer may include a first repeating unit derived from a monomer of formula (1):

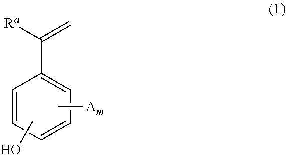

wherein R^{a} is hydrogen, fluorine, a substituted or unsubstituted C₁₋₅ alkyl, or a substituted or unsubstituted C₁₋₅ fluoroalkyl; each A is independently a halogen, a hydroxy, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted; and m is independently an integer of 0 to 4. Preferably, R^{a} is hydrogen or methyl, A is hydroxy, and m is 0 or 1.

For example, the first repeating unit may be derived from a monomer of formula (1a)

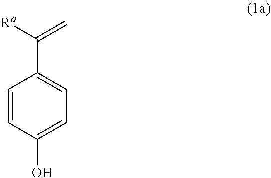

wherein R^{a} is the same as defined for formula (1).

The second repeating unit is derived from a monomer comprising a hydroxy-aryl group protected with an acetal or ketal group. In an embodiment, the second repeating unit may be derived from a monomer of formula (2):

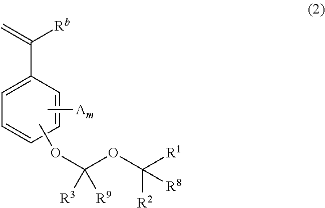

In formula (2), R^{b} is hydrogen, fluorine, a substituted or unsubstituted C₁₋₅ alkyl, or a substituted or unsubstituted C₁₋₅ fluoroalkyl; each A is independently a halogen, a hydroxy, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted; and m is independently an integer of 0 to 4. Preferably, R^{b} is hydrogen or methyl, A is hydroxy, and m is 0 or 1. Typically, A and m in the first repeating unit are the same as A and m, respectively, in the second repeating unit.

In formula (2), R′, R², and R⁸ are each independently hydrogen, a straight chain or branched C₁₋₂₀ alkyl, a straight chain or branched C₁₋₂₀ heteroalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted. In an embodiment, any two of R¹, R², and R⁸ together optionally may form a ring. In a further embodiment, a polycyclic structure can be formed by R¹, R², and R⁸ together.

In formula (2), R³ is a substituted or unsubstituted straight chain or branched C₁₋₂₀ alkyl, a substituted or unsubstituted monocyclic or polycyclic C₃₋₂₀ cycloalkyl, a substituted or unsubstituted monocyclic or polycyclic C₃₋₂₀ heterocycloalkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ heteroalkyl.

In formula (2), R⁹ is hydrogen, a substituted or unsubstituted straight chain or branched C₁₋₂₀ alkyl, a substituted or unsubstituted monocyclic or polycyclic C₃₋₂₀ cycloalkyl, a substituted or unsubstituted monocyclic or polycyclic C₃₋₂₀ heterocycloalkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ heteroalkyl.

In formula (2), R³ and R⁹ may optionally together form a ring.

In formula (2), one of R¹, R², or R⁸ and one of R³ or R⁹ optionally together form a ring.

For example, the second repeating unit may be derived from a monomer of formula (2a):

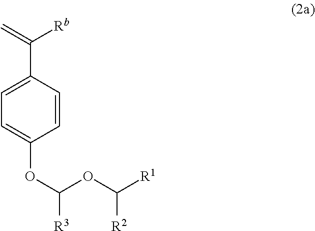

wherein R^{b}, R¹, R², and R³ are the same as defined for formula (2). In an embodiment, R¹ and R² are not both hydrogen. In an aspect, R¹ and R² together optionally may form a ring. In another aspect, R³ and one of IV or R² together optionally may form a ring.

Non-limiting examples of monomers of formula (2) include:

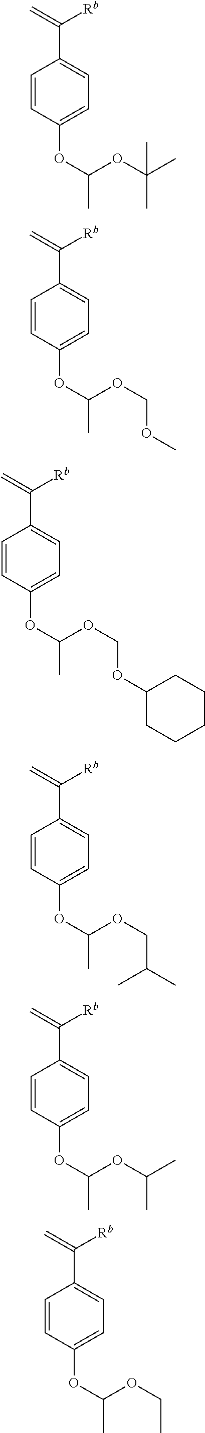

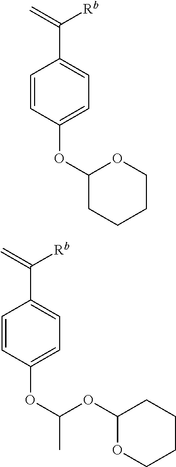

In a particular embodiment, the polymer may include the first repeating unit that is derived from a monomer of formula (1a) and the second repeating unit that is derived from a monomer of formula (2a).

The third repeating unit is derived from a (meth)acrylate monomer comprising a cycloaliphatic (monocyclic or polycyclic) group. As used herein, the “cycloaliphatic group” refers to both cycloalkyl and heterocycloalkyl groups. In an embodiment, the third repeating unit may be derived from a monomer of formula (3):

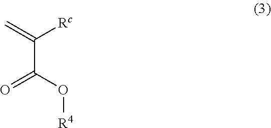

wherein R^{c} is hydrogen, fluorine, a substituted or unsubstituted C₁₋₅ alkyl, or a substituted or unsubstituted C₁₋₅ fluoroalkyl. In an embodiment, R^{c} is hydrogen or methyl.

In formula (3), is a monocyclic or polycyclic C₃₋₃₀ cycloalkyl, or a monocyclic or polycyclic C₃₋₃₀ heterocycloalkyl, each of which is unsubstituted or substituted, provided that does not include a tertiary carbon atom directly bonded to the divalent oxygen atom of the carboxylate group.

Non-limiting examples of monomers of formula (3) include:

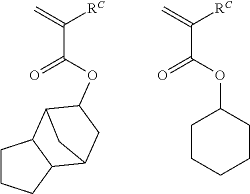

wherein R^{c} is as defined for formula (3).

In a particular embodiment, the polymer does not comprise a repeating unit derived from styrene.

The fourth repeating unit comprises an acid-sensitive group. In an embodiment, the acid-sensitive group is a tertiary ester acid group and may be derived from a monomer of formula (4a) or (4b):

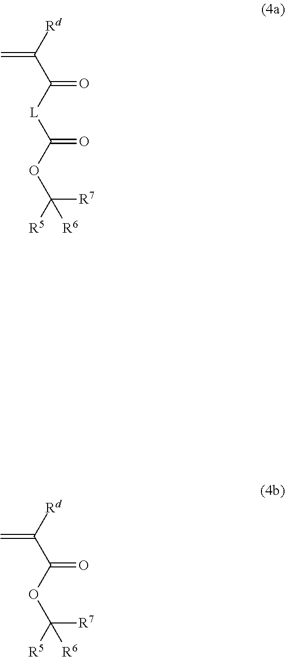

In formulae (4a) and (4b), R^{d} is hydrogen, fluorine, a substituted or unsubstituted C₁₋₅ alkyl, or a substituted or unsubstituted C₁₋₅ fluoroalkyl. In an embodiment, R^{d} is hydrogen or methyl.

In formulae (4a) and (4b), R⁵, R⁶, and R⁷ are each independently a straight chain or branched C₁₋₂₀ alkyl, a monocyclic or polycyclic C₃₋₂₀ cycloalkyl, a monocyclic or polycyclic C₃₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄₋₂₀ heteroaryl, each of which is substituted or unsubstituted, and any two of R⁵, R⁶, and R⁷ together optionally form a ring. Preferably, R⁵, R⁶, and R⁷ are each independently a straight chain or branched C₁₋₆ alkyl, or a monocyclic or polycyclic C₃₋₁₀ cycloalkyl, each of which is substituted or unsubstituted, and any two of R⁵, R⁶, and R⁷ together optionally form a ring. For example, R⁵ can be a substituted C₃ alkyl group of the formula —CH₂C(═O)CH₍₃₋ₙ₎Yₙ, where each Y is independently a substituted or unsubstituted C₃₋₁₀ heterocycloalkyl and n is 1 or 2.

In formula (4a), L is a linking unit including at least one carbon atom and at least one heteroatom. In an embodiment, L may include 1 to 10 carbon atoms. In another embodiment, L may be —OCH₂CH₂O—.

Non-limiting examples of monomers of formula (4a) include:

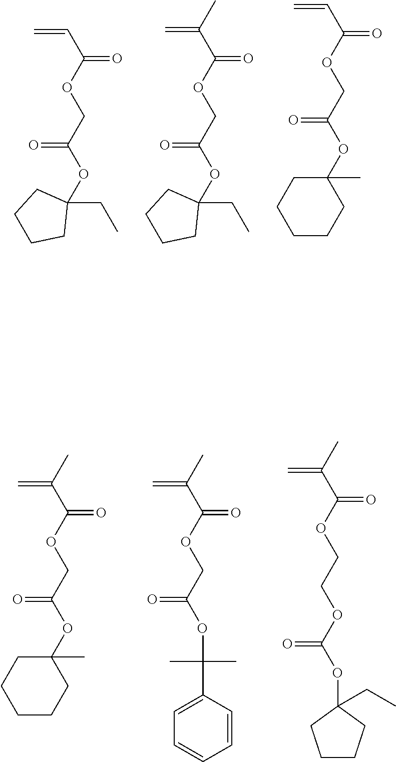

Non-limiting examples of monomers of formula (4b) include:

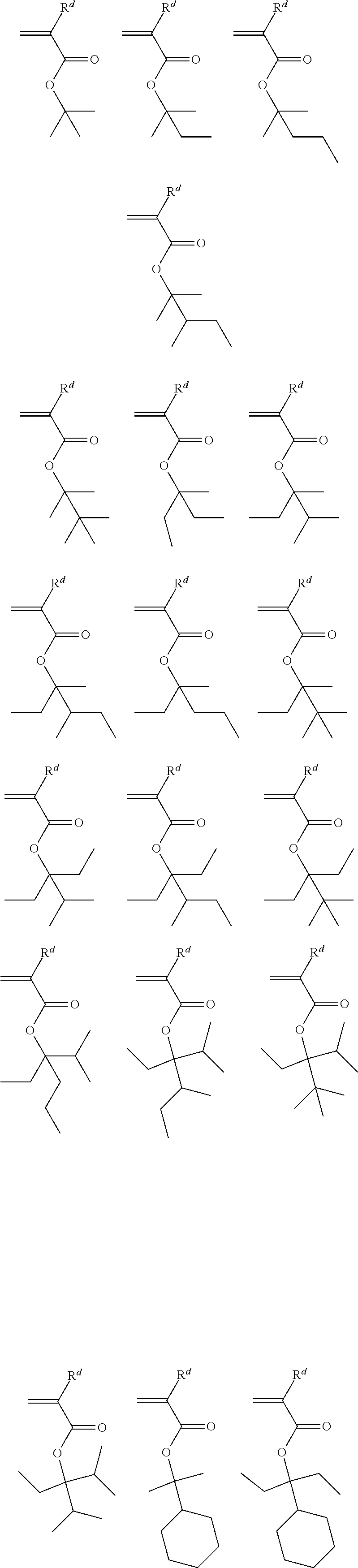

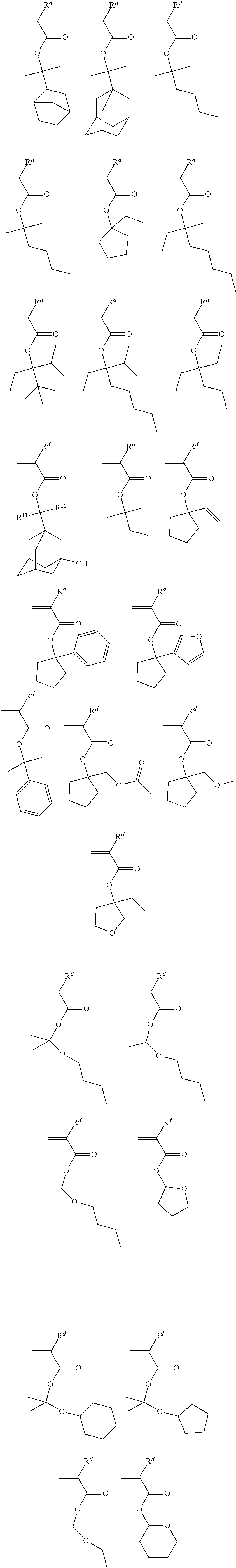

wherein R^{d} is as defined above; and R¹¹ and R¹² are each independently a straight chain or branched C₁₋₂₀ alkyl, a monocyclic or polycyclic C₃₋₂₀ cycloalkyl, a monocyclic or polycyclic C₃₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄₋₂₀ heteroaryl, each of which is substituted or unsubstituted.

In another embodiment, the fourth repeating unit may be derived from a monomer of the following formulae:

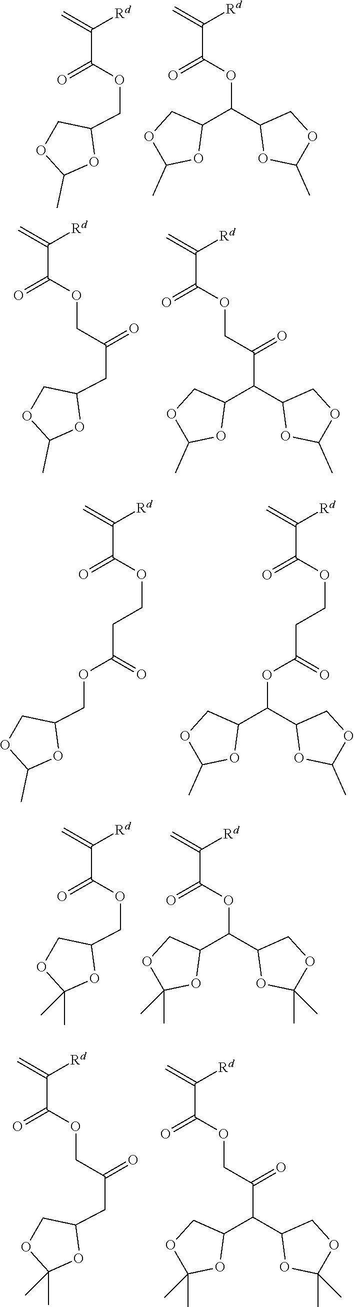

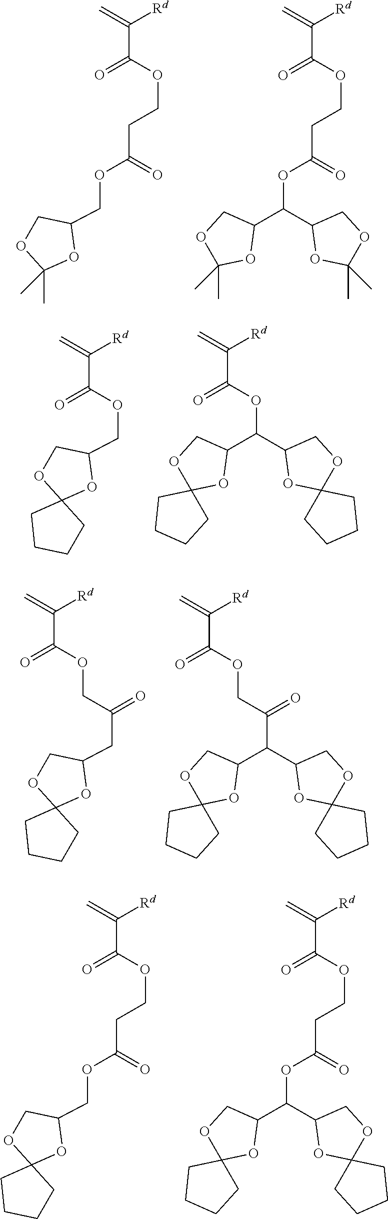

wherein R^{d} is as defined above.

In still another embodiment, the fourth repeating unit may be derived from a monomer of the following formulae:

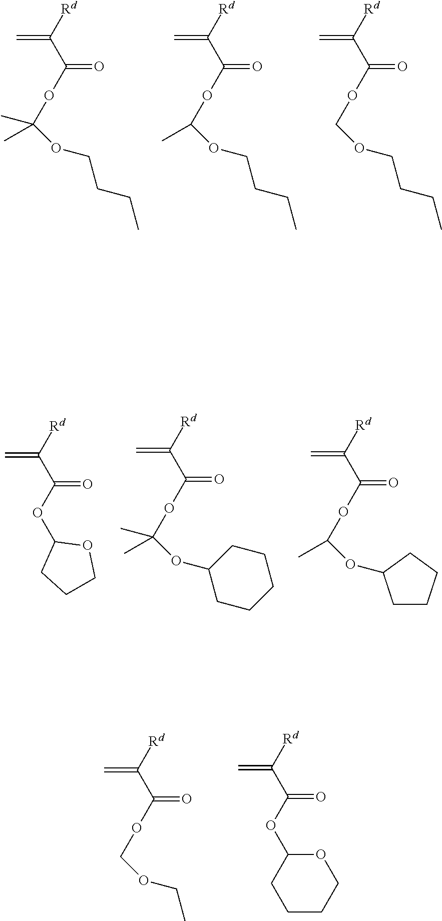

In an embodiment, the polymer may include the first repeating unit that is derived from the monomer of formula (1), the second repeating unit that is derived from the monomer of formula (2), the third repeating unit that is derived from the monomer of formula (3), and the fourth repeating unit that is derived from the monomer of formula (4a) or (4b). In a particular embodiment, the polymer may be a tetrapolymer that includes a first repeating unit that is derived from the monomer of formula (1), a second repeating unit that is derived from the monomer of formula (2), a third repeating unit that is derived from the monomer of formula (3), and a fourth repeating unit that is derived from the monomer of formula (4a) or (4b).

In an embodiment, polymer may include 45 to 70 mole percent (mol %), preferably 50 to 65 mol %, of the first repeating unit based on 100 mol % of total repeating units in the polymer.

In an embodiment, the polymer may include 5 to 45 mol %, preferably 10 to 30 mol %, of the second repeating unit based on 100 mol % of total repeating units in the polymer.

In an embodiment, the polymer may include 3 to 40 mol %, preferably 5 to 15 mol %, of the third repeating unit based on 100 mol % of total repeating units in the polymer.

In an embodiment, the polymer may include 5 to 30 mol %, preferably 8 to 23 mol %, of the fourth repeating unit based on 100 mol % of total repeating units in the polymer.

For example, the polymer may include 45 to 70 mol % of the first repeating unit, 5 to 45 mol % of the second repeating unit, 3 to 40 mol % of the third repeating unit, and 5 to 30 mol % of the fourth repeating, each based on 100 mol % of total repeating units in the polymer. For example, the polymer may include 50 to 65 mol %, of the first repeating unit, 10 to 30 mol %, of the second repeating unit, 5 to 15 mol %, of the third repeating unit, and 8 to 23 mol %, of the fourth repeating, each based on 100 mol % of total repeating units in the polymer.

The polymer may have a weight average molecular weight (M_{w}) from 2,000 grams per mole (g/mol) to 100,000 g/mol, for example, preferably from 10,000 to about 50,000 g/mol, more preferably from 12,000 to about 30,000 g/mol, with a polydispersity index (PDI) of 1.3 to 3, preferably 1.3 to 2, more preferably 1.4 to 2. Molecular weight is determined by gel permeation chromatography (GPC) using polystyrene standards.

The polymers may be prepared using any suitable methods in the art. For example, one or more monomers corresponding to the repeating units described herein may be combined, or fed separately, using suitable solvent(s) and initiator, and polymerized in a reactor. For example, the polymer may be obtained by polymerization of the respective monomers under any suitable conditions, such as by heating at an effective temperature, irradiation with actinic radiation at an effective wavelength, or a combination thereof.

Another embodiment provides a photoresist composition including the polymer, a photoacid generator, and a solvent.

In the photoresist compositions of the invention, the polymer is typically present in the photoresist composition in an amount of from 10 to 99.9 wt %, preferably from 25 to 99 wt %, more preferably 50 to 95 wt %, based on the weight of the total solids. It will be understood that total solids includes the polymer and other non-solvent components including, but not limited to, PAGs, photo-destroyable bases, quenchers, surfactants, additional polymers, and other additives.

The photoresist compositions may further include one or more polymers in addition to the polymer described above. For example, the photoresist compositions may include an additional polymer as described above but different in composition, or a polymer that is similar to those described above but does not include each of the four different requisite monomer types. Additionally or alternatively, the one or more additional polymers can include those well known in the photoresist art, for example, polyacrylates, polyvinylethers, polyesters, polynorbornenes, polyacetals, polyethylene glycols, polyamides, polyacrylamides, polyphenols, novolacs, styrenic polymers, polyvinyl alcohols.

In an embodiment, the photoresist composition may further include a second polymer that is different from the polymer of the invention, where the second polymer will exhibit a change in an alkaline developer to improve solubility. For example, the second polymer may be capable of switching solubility from insoluble to soluble in a 0.26 normality (N) tetramethylammonium hydroxide (TMAH) aqueous solution upon reaction with acid. The acid can be generated by exposure of a photoacid-generating compound in the photoresist composition to activating radiation. The photoacid-generating compound can be in a photoacid-generating repeat units in the second polymer, or in a non-polymer-bound photoacid generator. The change in solubility of the second polymer can be due to the reaction of photo-generated acid with a functional group of the second polymer. Exemplary functional groups may be, for example, hydroxy; alkoxy such as ethoxy, propoxy, isopropoxy; carboxyester, amino, amido, epoxy, imino, carboxyacid, anhydride, olefinic, acrylic, acetal, orthoester, vinyl ether, and combinations thereof.

The second polymer may be present in the photoresist composition in an amount of about 0.5 to 25 wt % or more, more preferably 0.5 to 20 wt % of the total photoresist solids, relative to the total solids (all components except solvent).

In an embodiment, the photoresist composition may further include a plasticizer compound or composition to promote the formation of a thick coating layer. Preferred plasticizers for use in the photoresists of the present invention are, for example, materials having one or more heteroatoms (particularly S or O), and preferably have a molecular weight of about 20 to 1000 g/mol, more typically about 20 to about 50, 60, 70, 80, 90 g/mol; Materials which have molecular weight of 100, 150, 200, 250, 300, 400 or 500 g/mol, such as adipates, sebacates and phthalates such as bis(2-butoxyethyl) adipate; bis(2-butoxyethyl) sebacate; bis(2-butoxyethyl) phthalate; 2-butoxyethyl oleate; diisodecyl adipate; diisodecyl glutarate and poly(ethylene glycol)s such as poly(ethylene glycol) acrylate, poly(ethylene glycol)-bis(2-ethylhexanoate), poly(ethylene glycol) dibenzoate, poly(ethylene glycol) dioleate, poly(ethylene glycol) monooleate, tri(ethylene glycol)-bis(2-ethylhexanoate), and the like.

One or more plasticizer compounds may suitably be present in the photoresist composition in an amount of about 0.5 to 20 wt % or more, more preferably 0.5 to 15 wt % of the total photoresist solids, relative to the total solids (all components except solvent).

The photoresist composition includes one or more photoacid generators (PAG)s. Photoacid generators generally include those photoacid generators suitable for the purpose of preparing photoresists. Photoacid generators include, for example, non-ionic oximes and various onium cation salts. Onium cations can be substituted or unsubstituted and include, for example, ammonium, phosphonium, arsonium, stibonium, bismuthonium, oxonium, sulfonium, selenonium, telluronium, fluoronium, chloronium, bromonium, iodonium, aminodiazonium, hydrocyanonium, diazenium (RN═N⁺R₂), iminium (R₂C═N⁺R₂), quaternary ammonium having two double-bonded substituents (R═N⁺═R), nitronium (NO₂⁺), bis(trarylphosphine)iminium ((Ar₃P)₂N⁺, tertiary ammonium having one triple-bonded substituent (R≡NH⁺), nitrilium (RC≡NR⁺), diazonium (N≡N⁺R), tertiary ammonium having two partially double-bonded substituents (R [symbol] N⁺H [symbol] R), pyridinium, quaternary ammonium having one triple-bonded substituent and one single-bonded substituent (R≡N⁺R), tertiary oxonium having one triple-bonded substituent (R≡O⁺), nitrosonium (N≡O⁺), tertiary oxonium having two partially double-bonded substituents (R [symbol] O⁺ [symbol] R), pyrylium (C₅H₅O⁺), tertiary sulfonium having one triple-bonded substituent (R≡S⁺), tertiary sulfonium having two partially double-bonded substituents (R [symbol] S⁺ [symbol] R), and thionitrosonium (N≡S⁺). In an embodiment, the onium ion is selected from a substituted or unsubstituted diaryiodonium, or a substituted and substituted triarylsulfonium. Examples of suitable onium salts can be found in U.S. Pat. Nos. 4,442,197, 4,603,101, and 4,624,912.

Suitable photoacid generators are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Another embodiment further provides a photoresist composition comprising a photoacid generator having formula G⁺A⁻, wherein A⁻ is an organic anion and G⁺ has formula (A):

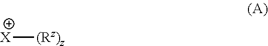

In formula (A), X may be S or I, each R^{z} may be halogenated or non-halogenated, and is independently a C₁₋₃₀ alkyl group; a polycyclic or monocyclic C₃₋₃₀ cycloalkyl group; a polycyclic or monocyclic C₄₋₃₀ aryl group, wherein when X is S, one of the R^{z} groups is optionally attached to one adjacent R^{z} group by a single bond, and z is 2 or 3, and wherein when X is I, z is 2, or when X is S, z is 3.

For example, cation G⁺ may be of formula (B), (C), or (D):

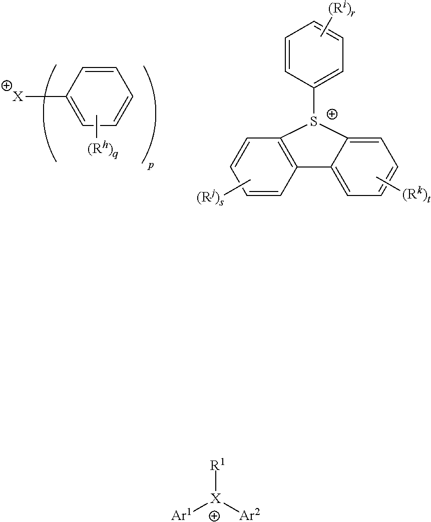

wherein X is I or S; R^{h}, Rⁱ, R^{j}, and R^{h} are unsubstituted or substituted and are each independently hydroxy, nitrile, halogen, C₁₋₃₀ alkyl, C₁₋₃₀ fluoroalkyl, C₃₋₃₀ cycloalkyl, C₁₋₃₀ fluorocycloalkyl, C₁₋₃₀ alkoxy, C₃₋₃₀ alkoxycarbonylalkyl, C₃₋₃₀ alkoxycarbonylalkoxy, C₃₋₃₀ cycloalkoxy, C₅₋₃₀ cycloalkoxycarbonylalkyl, C₅₋₃₀ cycloalkoxycarbonylalkoxy, C₁₋₃₀ fluoroalkoxy, C₃₋₃₀ fluoroalkoxycarbonylalkyl, C₃₋₃₀ fluoroalkoxycarbonylalkoxy, C₃₋₃₀ fluorocycloalkoxy, C₅₋₃₀ fluorocycloalkoxycarbonylalkyl, C₅₋₃₀ fluorocycloalkoxycarbonylalkoxy, C₆₋₃₀ aryl, C₆₋₃₀ fluoroaryl, C₆₋₃₀ aryloxy, or C₆₋₃₀ fluoroaryloxy, each of which is unsubstituted or substituted; Ar¹ and Ar² are independently C₁₀₋₃₀ fused or singly bonded polycyclic aryl groups; R¹ is a lone pair of electrons where X is I or a C₆₋₂₀ aryl group where X is S; p is an integer of 2 or 3; wherein when X is I, p is 2, and wherein when X is S, p is 3; q and r are each independently an integer from 0 to 5, and t and s are each independently an integer from 0 to 4.

In an embodiment, the PAG is a sulfonium salt represented by formula (6):

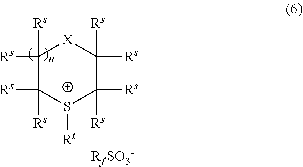

wherein R^{t} may be a substituted or unsubstituted C₂₋₂₀ alkenyl, a substituted or unsubstituted C₃₋₂₀ cycloalkyl, a substituted or unsubstituted C₅₋₃₀ aryl, or a substituted or unsubstituted C₄₋₃₀ heteroaryl. In another embodiment, R^{t} may be a substituted or unsubstituted C₅₋₃₀ aryl or a substituted or unsubstituted C₄₋₃₀ heteroaryl. For example, R^{t} may be a substituted phenyl group. In an embodiment, R^{t} may be a phenyl group substituted with one or more C₁₋₃₀ alkyl or C₃₋₈ cycloalkyl, for example, C₁₋₅ alkyl or C₃₋₆ cycloalkyl. In an embodiment, R^{t} may optionally include an acid-sensitive functional group capable of being hydrolyzed at pH<7.0, for example, a tertiary ester, a tertiary ether, or a tertiary carbonate group.

In formula (6), R^{s} at each occurrence can be the same or different, and may each independently be hydrogen, a halogen, a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a monocyclic or polycyclic C₃₋₂₀ cycloalkyl, a monocyclic or polycyclic C₃₋₂₀ fluorocycloalkyl, a monocyclic or polycyclic C₃₋₂₀ cycloalkenyl, a monocyclic or polycyclic C₃₋₂₀ fluorocycloalkenyl, a monocyclic or polycyclic C₃₋₂₀ heterocycloalkyl; a monocyclic or polycyclic C₃₋₂₀ heterocycloalkenyl; a monocyclic or polycyclic C₆₋₂₀ aryl, a monocyclic or polycyclic C₆₋₂₀ fluoroaryl, a monocyclic or polycyclic C₄₋₂₀ heteroaryl, or a monocyclic or polycyclic C₄₋₂₀ fluoroheteroaryl, each of which except hydrogen may be substituted or unsubstituted. In an embodiment, each R^{s} may be hydrogen.

Any two of R^{s} groups may be optionally connected via Z′ to form a ring, wherein Z′ may be a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ may be hydrogen or a C₁₋₂₀ alkyl group.

Each R^{s} may be optionally substituted, independently from other R^{s} groups, with at least one selected from —OY, —NO₂, —CF₃, —C(═O)—C(═O)—Y, —CH₂OY, —CH₂Y, —SY, —B(Y)ₙ, —C(═O)NRY, —NRC(═O)Y, —(C═O)OY, and —O(C═O)Y, wherein Y is a straight chain or branched C₁₋₂₀ alkyl, a straight chain or branched C₁₋₂₀ fluoroalkyl, a straight chain or branched C₂₋₂₀ alkenyl, a straight chain or branched C₂₋₂₀ fluoroalkenyl, a straight chain or branched C₂₋₂₀ alkynyl, a straight chain or branched C₂₋₂₀ fluoroalkynyl, a C₆₋₂₀ aryl, a C₆₋₂₀ fluoroaryl, or an acid-sensitive functional group capable of being hydrolyzed at pH<7.0, such as a tertiary ester, tertiary ether, or tertiary carbonate group.

In formula (6), X may be a divalent linking group such as O, S, Se, Te, NR″, S═O, S(═O)₂, C═O, (C═O)O, O(C═O), (C═O)NR″, or NR″(C═O), wherein R″ may be hydrogen or a C₁₋₂₀ alkyl. n may be an integer of 0, 1, 2, 3, 4, and 5. In an embodiment, X may be 0.

In formula (6), R_{f}SO₃⁻ is a fluorinated sulfonate anion, wherein R_{f} is a fluorinated group. In an embodiment, R_{f} may z be —C(R²⁰)_{y}(R²¹)_{z}, wherein R²⁰ may be independently selected from F and fluorinated methyl, R²¹ may be independently selected from hydrogen, C₁₋₅ linear or branched or cycloalkyl and C₁₋₅ linear or branched or cyclic fluorinated alkyl, y and z may be independently an integer from 0 to 3, provided that the sum of y and z is 3 and at least one of R²⁰ and R²¹ contains fluorine, wherein the total number of carbon atoms in R_{f} may be from 1 to 6. In the formula —C(R²⁰)_{y}(R²¹)_{z} both R²⁰ and R²¹ are attached to C. Preferably, there is at least one fluorine atom or fluorinated group bonded to the carbon atom at the alpha position with respect to the SO₃⁻ group. In an embodiment, y may be 2, and z may be 1. In these embodiments, each R²⁰ may be F, or one R¹² may be F and the other R²⁰ may be fluorinated methyl. A fluorinated methyl may be monofluoromethyl (—CH₂F), difluoromethyl (—CHF₂), and trifluoromethyl (—CF₃). In another embodiment, R²¹ may be independently selected from C₁₋₅ linear or branched fluorinated alkyl. A fluorinated alkyl may be partially fluorinated or perfluorinated alkyl.

The one or more PAGs are typically present in the photoresist compositions in an amount of from 0.1 to 10 wt % and preferably from 0.1 to 5 wt %, based on total solids.

The photoresist composition further includes a solvent. The solvent may be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), aa polar aprotic solvent (such as dimethyl sulfoxide, dimethyl formamide, and the like), or a combination thereof. The solvent can be present in the photoresist compositions in an amount of from 40 to 99 wt %, preferably from 40 to 70 wt %, based on the total weight of the photoresist composition.

The photoresist composition may further include one or more optional additives. For example, optional additives may include actinic and contrast dyes, anti-striation agents, plasticizers, speed enhancers, sensitizers, photo-destroyable bases, basic quenchers, surfactants, and the like, or combinations thereof. If present, the optional additives are typically present in the photoresist compositions in an amount of from 0.01 to 10 wt % based on total solids.

Exemplary photo-destroyable bases include, for example, photo-decomposable cations, and preferably those also useful for preparing acid generator compounds, paired with an anion of a weak (pKa>2) acid such as, for example, a C₁₋₂₀ carboxylic acid. Exemplary carboxylic acids include formic acid, acetic acid, propionic acid, tartaric acid, succinic acid, cyclohexylcarboxylic acid, benzoic acid, salicylic acid, and the like.

Exemplary basic quenchers include, for example: linear aliphatic amines such as triisopropanolamine, n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an embodiment, the photoresist composition further includes a surfactant polymer including a fluorine-containing repeating unit.

The photoresist compositions as disclosed herein may advantageously be coated in a single application to provide a thick photoresist layer or may be coated in multiple application to provide the thick photoresist layer. The thickness of the photoresist layer in a dried state is typically greater than 5 micrometers (μm), for example from 5 to 50 μm, preferably 10 to 30 μm, more preferably 15 to 30 μm. As used herein, the “dried state” refers to the photoresist composition comprising 25 wt % or less, for example, 12 wt % or less, 10 wt % or less, 8 wt % or less, or 5 wt % or less of the solvent, based on the total weight of the photoresist composition. Alternatively, it may be desirable to use the photoresist compositions of the invention in standard thin-layer applications, for example, photoresist layers having a thickness of from 20 to 100 nm for EUV lithography applications, or from 500 nm to 5 μm for thin KrF (248 nm) lithography applications.

Also provided is a coated substrate formed from the photoresist composition. Such a coated substrate may include: (a) a substrate, and (b) a layer of the photoresist composition disposed over the substrate.

Substrates may be any dimension and shape, and are preferably those useful for photolithography, such as silicon, silicon dioxide, silicon-on-insulator (SOI), strained silicon, gallium arsenide, coated substrates including those coated with silicon nitride, silicon oxynitride, titanium nitride, tantalum nitride, ultrathin gate oxides such as hafnium oxide, metal or metal coated substrates including those coated with titanium, tantalum, copper, aluminum, tungsten, alloys thereof, and combinations thereof. Preferably, the surfaces of substrates herein include critical dimension layers to be patterned including, for example, one or more gate-level layers or other critical dimension layers on the substrates for semiconductor manufacture. Such substrates may preferably include silicon, SOI, strained silicon, and other such substrate materials, formed as circular wafers having dimensions such as, for example, 20 cm, 30 cm, or greater in diameter, or other dimensions useful for wafer fabrication production.

Further provided is a method of forming a pattern that includes applying a layer of the photoresist composition on a substrate; drying the applied photoresist composition to form a photoresist composition layer; exposing the photoresist composition layer to activating radiation; heating the exposed photoresist composition layer; and developing the exposed composition layer to form a resist pattern.

Application of the photoresist may be accomplished by any suitable method, including spin coating, spray coating, dip coating, doctor blading, or the like. For example, applying the layer of photoresist may be accomplished by spin-coating the photoresist in solvent using a coating track, in which the photoresist is dispensed on a spinning wafer. During dispensing, the wafer may be spun at a speed of up to 4,000 rpm, for example, from about 200 to 3,000 rpm, for example, 1,000 to 2,500 rpm. The coated wafer is spun to remove solvent, and soft-baked on a hot plate to remove residual solvent and reduce free volume to densify the film. The soft-bake temperature is typically from 90 to 170° C., for example, from 110 to 150° C. The heating time is typically from 10 seconds to 20 minutes, for example, from 1 minute to 10 minutes, or from 1 minute to 5 minutes. The heating time can be readily determined by one of ordinary skill in the art based on the ingredients of the composition.

The casting solvent can be any suitable solvent known to one of ordinary skill in the art. For example, the casting solvent can be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. The choice of the casting solvent depends on a particular photoresist composition and can be readily made by one of ordinary skill in the art based on knowledge and experience. The composition may then be dried by using conventional drying methods known to one of ordinary skill in the art.

The photoresist composition may be prepared by dissolving the polymer, the PAG, and any optional components in the appropriate amounts in the casting solvent. The photoresist composition or one or more of the components of the photoresist composition can be optionally subjected to a filtration step and/or ion exchange process using an appropriate ion exchange resin for purification purposes.

Exposure is then carried out using an exposure tool such as a stepper or scanner, in which the film is irradiated through a pattern mask and thereby is exposed pattern-wise. The method may use advanced exposure tools generating activating radiation at wavelengths capable of high-resolution patterning including excimer lasers, such as KrF and EUV exposure tools. It will be appreciated that exposure using the activating radiation decomposes the PAG in the exposed areas and generates acid, and that the acid then effectuates a chemical change in the polymer (deblocking the acid sensitive group to generate a base-soluble group in the case of positive resists, or alternatively, catalyzing a crosslinking reaction in the exposed areas for negative resists). The resolution of such exposure tools may be less than 30 nm.

Heating of the exposed composition may take place at a temperature of 90 to 170° C., for example, 100 to 150° C., or 110 to 140° C., or 110 to 130, or 110 to 120° C. The heating time may vary from 30 seconds to 20 minutes, for example, from 30 seconds to about 10 minutes, or from 50 seconds to 2 minutes. The heating time can be readily determined by one of ordinary skill in the art based on the components of the composition.

Developing the exposed photoresist layer is then accomplished by treating the exposed layer with a suitable developer capable of selectively removing the exposed portions of the film (in the case of a positive tone development (PTD) process) or removing the unexposed portions of the film (in the case of a negative tone development (NTD) process). Application of the developer may be accomplished by any suitable method such as described above with respect to application of the photoresist composition, with spin coating being typical. Typical developers for a PTD process include aqueous base developers, for example, quaternary ammonium hydroxide solutions such as tetramethylammonium hydroxide (TMAH), typically 0.26N TMAH, tetraethylammonium hydroxide, tetrabutyl ammonium hydroxide, sodium hydroxide, potassium hydroxide, sodium carbonate, potassium carbonate, and the like. Typical developers for an NTD process include an organic solvent-based developer, chosen for example, from one or more of an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate (nBA), propylene glycol monomethyl ether acetate (PGMEA), ethyl lactate (EL), hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. In an embodiment, the solvent developer may be a miscible mixture of solvents, for example, a mixture of an alcohol (iso-propanol) and ketone (acetone). For an NTD process, the developer is typically nBA or 2-heptanone. The choice of the developer solvent depends on a particular photoresist composition and can be readily made by one of ordinary skill in the art based on knowledge and experience.

The photoresist may, when used in one or more such pattern-forming processes, be used to fabricate semiconductor devices such as memory devices, processor chips (CPUs), graphics chips, optoelectronic chips, and other such devices.

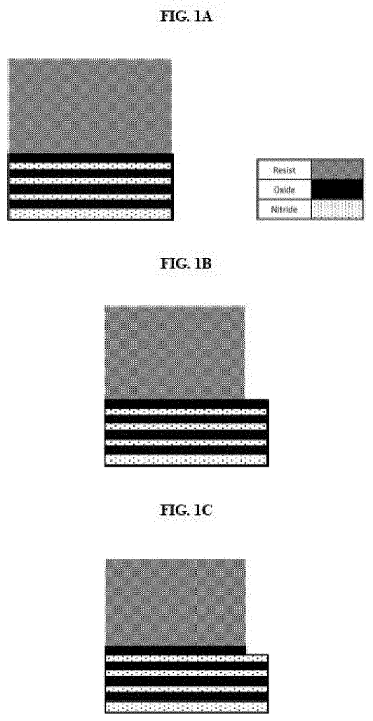

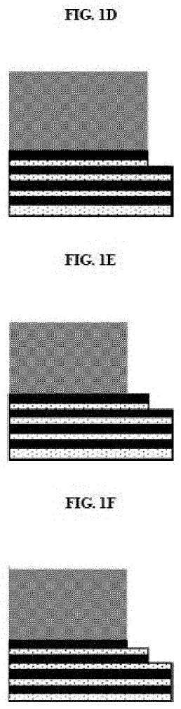

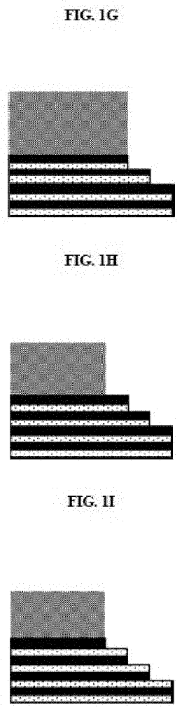

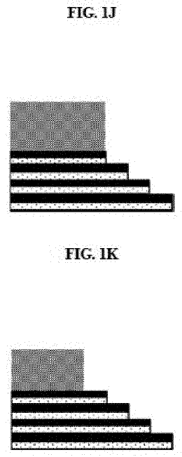

The pattern forming method may further include forming a staircase pattern in the substrate using the photoresist composition layer as an etch mask, wherein the staircase patter comprises a plurality of stairs. FIGS. 1A to 1K illustrate a method of forming a staircase pattern in accordance with an embodiment (Hong Xiao “3D IC Devices, Technologies, and Manufacturing” SPIE Press, Bellingham Wash. USA).

FIG. 1A shows a structure having a multilayer deposition of alternated silicon oxide (“Oxide”) and silicon nitride (“Nitride”) layers on a silicon surface with a photoresist (“Resist”) layer coated on the wafer surface as an etch mask. The oxide and nitride layers can be formed by various techniques known in the art, for example, chemical vapor deposition (CVD) such as plasma-enhanced CVD (PECVD) or low-pressure CVD (LPCVD). The photoresist layer can be formed as described above. Typically, the photoresist layer is formed by a spin-coating process. The photoresist layer is next patterned by exposure through a patterned photomask and developed as described above, with the resulting structure shown in FIG. 1B. After that, a sequential series of well-controlled oxide and nitride etch and resist trim steps are performed as follows. FIG. 1C shows the structure after the first silicon oxide etch, and FIG. 1D shows the structure after the first silicon nitride etch. After the first pair of oxide and nitride are etched away, a controlled photoresist trim step is performed (FIG. 1E). The trimmed photoresist is then used to etch the first and the second series of oxide and nitride, as shown in FIGS. 1F-G. The photoresist is then trimmed again (FIG. 1H) and the first, second and third pair of oxide/nitride are etched (FIGS. 1I-J). The controlled photoresist trimming is then performed again (FIG. 1K). Suitable oxide and nitride etch and resist trim processes and chemistries are known in the art, with dry-etching processes being typical.

The number of times the photoresist layer can be trimmed may be limited, for example, by its original thickness and etch selectivity. After the minimum thickness limit is reached, the remaining resist is typically stripped, and another photoresist layer formed in its place. The new photoresist layer is patterned, the oxide and nitride layers etched, and resist layer trimmed as described above with respect to the original photoresist layer, to continue formation of the staircase pattern. This process can be repeated multiple times until the desired staircase pattern is completed, typically, when the pattern reaches a desired surface of the substrate, typically the silicon surface of the substrate.

Hereinafter, the present disclosure is illustrated in more detail with reference to examples. However, these examples are exemplary, and the present disclosure is not limited thereto.

### EXAMPLES

Preparation of Photoresist Terpolymers A-1 to A-4

Poly[p-hydroxystyrene-co-styrene-co-tert-butyl acrylate] (A-1), poly[p-hydroxystyrene-co-styrene-co-1-ethylcyclopentyl methacrylate] (A-2), poly[p-hydroxystyrene-co-hexahydro-4,7-methanoindan-5-ol acrylate-co-tert-butyl acrylate] (A-3), and poly[p-hydroxystyrene-co-hexahydro-4,7-methanoindan-5-ol acrylate-co-tert-butyl acrylate] (A-4) were synthesized by free radical polymerization using the method described in U.S. Patent Application Publication No. US 2002/0156199 A1 of Sheehan et al.

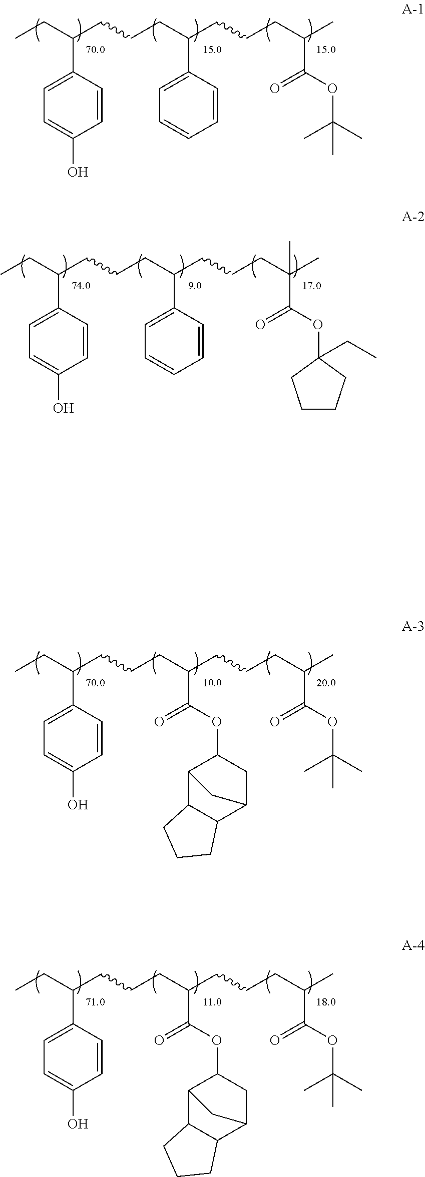

Preparation of Photoresist Tetrapolymer B-1

A 500 mL round-bottom flask was charged with 33.1 g of polymer A-1 and 380 mL propylene glycol monomethyl ether acetate (PGMEA) to form a solution. Reduced pressure was applied to the reaction flask to concentrate the solution and achieve a water content of less than 200 ppm by weight. The solution was purged with nitrogen for 40 minutes. 3.25 g of ethyl vinyl ether was injected into the solution, followed by 0.061 g of trifluoroacetic acid (TFA, 20% solution in PGMEA) in a dropwise manner. The reaction mixture was then stirred at room temperature (about 23° C.) for about 19 hours. The resulting product solution was filtered through a column of basic alumina and then filtered through an in-line PTFE membrane filter (0.2 μm pore size, available as ACRO 50). The solution was concentrated under reduced pressure to produce 50% wt solution of tetrapolymer B-1 in PGMEA. Tetrapolymer B-1 had an Mw of 21.0 kg/mol and a PDI of 1.75, as determined by GPC using polystyrene standards.

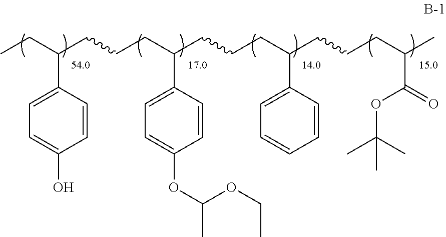

Preparation of Photoresist Tetrapolymer B-2

A 1 L round-bottom flask was charged with 41.8 g of polymer A-2 and 500 mL of PGMEA to form a solution. Reduced pressure was applied to the reaction flask to concentrate the solution and achieve a water content of less than 200 ppm by weight. The solution was purged with nitrogen for 40 minutes. 4.47 g of ethyl vinyl ether was injected into the solution, followed by 0.085 g of trifluoroacetic acid (TFA, 20% solution in PGMEA) in a dropwise manner. The reaction mixture was then stirred at room temperature (about 23° C.) for about 19 hours. The resulting product solution was filtered through a column of basic alumina and then filtered through an in-line PTFE membrane filter (0.2 μm pore size, available as ACRO 50). The solution was concentrated under reduced pressure to produce 50% wt solution of tetrapolymer B-2 in PGMEA. Tetrapolymer B-1 had an Mw of 18.5 kg/mol and a PDI of 1.60, as determined by GPC using polystyrene standards.

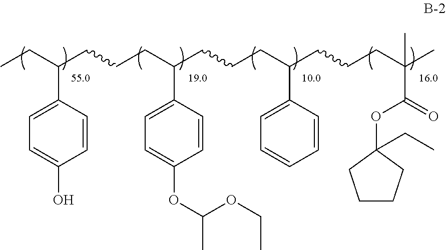

Preparation of Photoresist Terpolymers A-5 and A-6

Terpolymers A-5 and A-6 were prepared in an analogous manner as terpolymers A-1 to A-4. Table 1 shows the monomers used to prepare terpolymers A-1 to A-6 and the corresponding properties of the terpolymers. The amounts of repeating units in the terpolymers are in mol %.

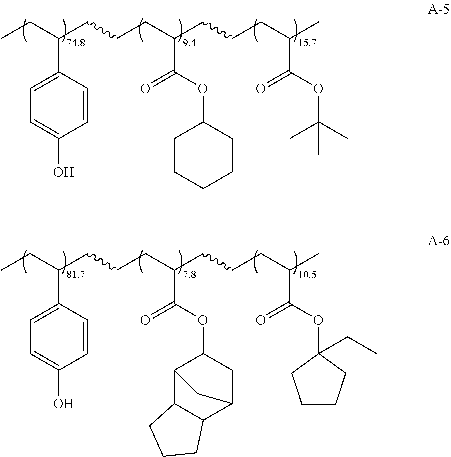

TABLE 1

| Terpoly- | Monomer 1 | Monomer 3 | Monomer 4 | Mw | |
|---|---|---|---|---|---|
| mer | (mol %) | (mol %) | (mol %) | (kg/mol) | PDI |
| A-1 | HS | ST | tBA | 22.9 | 1.82 |
| | (70.0%) | (15.0%) | (15.0%) | | |
| A-2 | HS | ST | ECPMA | 23.8 | 1.56 |
| | (74.0%) | (9.0%) | (17.0%) | | |
| A-3 | HS | TCDA | tBA | 22.4 | 1.68 |
| | (70.0%) | (10.0%) | (20.0%) | | |
| A-4 | HS | TCDA | tBA | 18.0 | 1.83 |
| | (71.0%) | (11.0%) | (18.0%) | | |
| A-5 | HS | CHA | tBA | 17.5 | 1.57 |
| | (74.8%) | (9.4%) | (15.7%) | | |
| A-6 | HS | TCDA | ECPA | 17.4 | 1.73 |
| | (81.7%) | (7.8%) | (10.5%) | | |

The monomers used to prepare the polymers have the following structures:

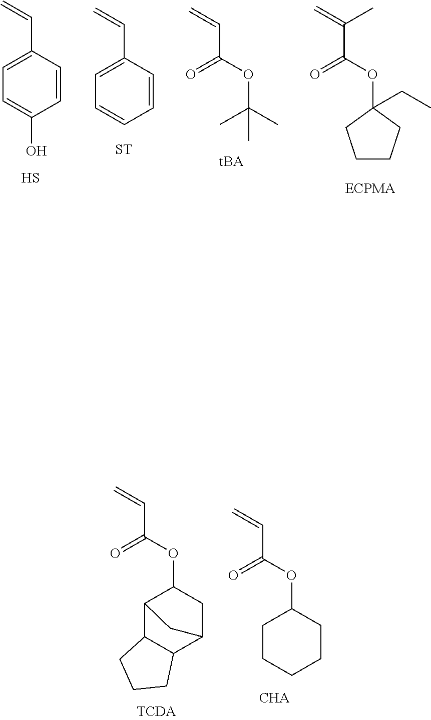

Preparation of Photoresist Tetrapolymers B-3 to B-7

The inventive tetrapolymers B-3 to B-7 were prepared in the same manner as the comparative tetrapolymers B-1 and B-2. Table 1 shows the monomers used to prepare the respective units of tetrapolymers B-1 to B-7 and the corresponding properties of the tetrapolymers. The amounts of repeating units in the tetrapolymers are in mol %.

TABLE 2

| | | Monomer 1 | Monomer 2 | Monomer 3 | Monomer 4 | Mw | |
|---|---|---|---|---|---|---|---|
| Tetrapolymer | Terpolymer | (mol %) | (mol %) | (mol %) | (mol %) | (kg/mol) | PDI |
| B-1* | A-1 | HS | EVE | ST | tBA | 21.0 | 1.75 |
| | | (54.0%) | (17.0%) | (14.0%) | (15.0%) | | |
| B-2* | A-2 | HS | EVE | ST | ECPMA | 18.5 | 1.60 |
| | | (55.0%) | (19.0%) | (10.0%) | (16%) | | |
| B-3 | A-3 | HS | EVE | TCDA | tBA | 23.3 | 1.63 |
| | | (55.0%) | (14.0%) | (11.0%) | (20.0%) | | |
| B-4 | A-3 | HS | iPrVE | TCDA | tBA | 25.8 | 1.59 |
| | | (55.0%) | (14.0%) | (11.0%) | (20.0%) | | |
| B-5 | A-4 | HS | iPrVE | TCDA | tBA | 20.0 | 1.57 |
| | | (53.2%) | (17.7%) | (11.3%) | (17.8%) | | |
| B-6 | A-5 | HS | iPrVE | CHA | tBA | 16.4 | 1.52 |
| | | (57.6%) | (17.4%) | (9.3%) | (15.7%) | | |
| B-7 | A-6 | HS | iPrVE | TCDA | ECPA | 18.9 | 1.58 |
| | | (62.5%) | (19.1%) | (8.3%) | (10.0%) | | |

*denotes comparative example

The abbreviations and structures of the monomer units of the tetrapolymers are the same as those shown above for the monomers of the terpolymers. For the tetrapolymers of B-1 to B-7, the structures of EVE and iPrVE in Table 2 are as follows:

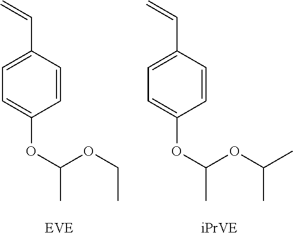

Photoresist Compositions

### Example 1 (Comparative)

17.525 g of terpolymer A-1, 0.571 g of PAG-A, 2.209 g of Additive-A, 1.767 g of Additive-B, 0.008 g of Quencher, and 0.011 g of Surfactant were dissolved in 22.327 g of PGMEA, 4.186 g of propylene glycol methyl ether (PGME), and 1.395 g of gamma-butyrolactone (GBL). The resulting mixture was rolled on a roller for 12 hours and then filtered through a PTFE filter having a 1 micron pore size.

The photoresist compositions of Examples 2 to 11 were prepared in an analogous manner by combining the components shown in Table 3. Examples 1 to 5 are comparative.

TABLE 3

| | Polymer | PAG-A | Additive A | Additive B | Quencher | Surfactant | PGMEA | PGME | GBL |
|---|---|---|---|---|---|---|---|---|---|
| Example | (g) | (g) | (g) | (g) | (g) | (g) | (g) | (g) | (g) |
| 1* | A-1 | 0.571 | 2.209 | 1.767 | 0.008 | 0.011 | 22.327 | 4.186 | 1.395 |
| | (17.525) | | | | | | | | |
| 2* | B-l | 0.571 | 2.209 | 1.767 | 0.008 | 0.011 | 22.327 | 4.186 | 1.395 |
| | (17.525) | | | | | | | | |
| 3* | A-2 | 0.556 | 2.150 | 1.720 | 0.008 | 0.011 | 10.290 | 16.785 | 1.425 |
| | (17.056) | | | | | | | | |
| 4* | B-2 | 0.571 | 2.209 | 1.767 | 0.008 | 0.011 | 22.327 | 4.186 | 1.395 |
| | (17.525) | | | | | | | | |
| 5* | A-3 | 0.571 | 2.209 | 1.767 | 0.008 | 0.011 | 22.327 | 4.186 | 1.395 |
| | (17.525) | | | | | | | | |
| 6 | B-3 | 0.571 | 2.209 | 1.767 | 0.008 | 0.011 | 22.327 | 4.186 | 1.395 |
| | (17.525) | | | | | | | | |
| 7 | B-3 | 0.571 | 1.105 | 0.884 | 0.008 | 0.011 | 22.327 | 4.186 | 1.395 |
| | (19.513) | | | | | | | | |
| 8 | B-4 | 0.540 | 2.090 | 1.672 | 0.008 | 0.010 | 19.278 | 3.615 | 1.205 |
| | (16.582) | | | | | | | | |
| 9 | B-5 | 0.720 | 2.787 | 2.230 | 0.010 | 0.014 | 25.704 | 4.820 | 1.607 |
| | (22.109) | | | | | | | | |
| 10 | B-6 | 0.302 | 1.695 | 0.847 | 0.008 | 0.010 | 22.671 | 1.260 | 1.260 |
| | (16.949) | | | | | | | | |
| 11 | B-7 | 0.302 | 1.695 | 0.847 | 0.008 | 0.010 | 22.671 | 1.260 | 1.260 |
| | (16.949) | | | | | | | | |

*denotes comparative example

In Table 3, the following components were used. Quencher is N—N-diethyldodecanamide; Additive-A is MARUKA LYNCUR N PADG (Maruzen Photochemical Co. Ltd.); Additive-B is MARUKA LYNCUR NORES (Maruzen Photochemical Co. Ltd.); and Surfactant is POLYFOX PF-656 surfactant (Omnova Solutions, Inc.).

PAG-A is the photoacid generator and is prepared as shown in Scheme 1.

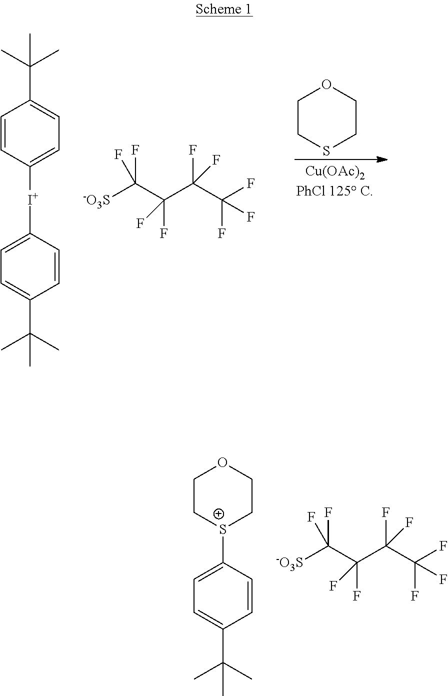

In a 1 L round bottom flask, equipped with a reflux condenser and stirring bar, bis(4-(tert-butyl) phenyl)iodonium perfluorobutane sulfonate (149 g, 216 mmol), and 1,4-oxathiane (25 g, 240 mmol) were dispersed in 400 mL of chlorobenzene. Copper (II) acetate (2.18 g, 12 mmol) was added to the reaction mixture. The reaction was heated at 125° C. for 6 h. The reaction was then cooled to room temperature, diluted with dichloromethane (500 mL), and washed with deionized water (3×200 mL). The organic layer was concentrated to approximatively 100 mL under reduced pressure. Precipitation using methyl tert-butyl ether (MTBE) afforded 105 g of PAG-A (81.5%) as a crystalline white solid.

Wafer Processing

KrF contrast and lithographic evaluations were carried out on 200 mm silicon wafers using a TEL Mark 8 track. Silicon wafers were primed with hexamethydisilazane (HMDS) at a rate of 180° C./60 s. HMDS-primed wafers were spin-coated with the aforementioned photoresist compositions and baked for 70 seconds at 150° C. to yield a film thickness of about 15 μm. The photoresist-coated wafers were then exposed by ASML 300 KrF stepper through a blank mask. The exposure started at 1.0 mJ/cm² and increased by an increment of 1.0 mJ/cm² to expose 100 dies in a 10×10 array on the wafer. The exposed wafers were post-exposure baked at 110° C. for 50 seconds and then developed using a 0.26 N tetramethylammonium hydroxide solution (CD-26) for 45 seconds. The developed wafers were visually checked for any residue and to determine the clearing dose (E₀) which is the minimum dose that is required to clear the film completely.

Etch Void Evaluation

Prior to etch testing, photoresist formulations were spin-coated on HMDS-primed Si wafer and baked at 150° C. for 70 seconds. Etch tests were performed with a Plasma-Therm LLC 790+ RIE tool following the etch recipe as shown in the Table 4. For scanning electron microscopy (SEM) imaging, wafers were cleaved and mounted on 25 mm×6 mm aluminum sample stubs with the aid of double-sided carbon tape. A Denton Vacuum DV-502A plasma coater was used to sputter a coating of iridium (4 nm) to render the samples conductive under the electron beam. An AMRAY 4200 was operated at 15 kV under a working distance of about 10 mm to evaluate the surface roughness and void formation within the film.

TABLE 4

| | Cycle #1 | | | Cycle #2 | | | Cycle #3 | | | Cycle #4 | | |
|---|---|---|---|---|---|---|---|---|---|---|---|---|
| | C1-1 | C1-2 | C1-3 | C2-1 | C2-2 | C2-3 | C3-1 | C3-2 | C3-3 | C4-1 | C4-2 | C4-3 |
| Time | 600 | 120 | 600 | 600 | 120 | 600 | 600 | 120 | 600 | 600 | 120 | 600 |
| (seconds) | | | | | | | | | | | | |
| Pressure | 10.0 | 10.0 | 75.0 | 10.0 | 10.0 | 75.0 | 10.0 | 10.0 | 75.0 | 10.0 | 10.0 | 75.0 |
| (mT) | | | | | | | | | | | | |
| CF₄ | 0 | 0 | 0 | 0 | 0 | 0 | 0 | 0 | 0 | 0 | 0 | 0 |
| (sccm) | | | | | | | | | | | | |
| CHF₃ | 50 | 0 | 0 | 50 | 0 | 0 | 50 | 0 | 0 | 50 | 0 | 0 |
| (sccm) | | | | | | | | | | | | |
| SF₆ | 0 | 66 | 0 | 0 | 66 | 0 | 0 | 66 | 0 | 0 | 66 | 0 |
| (sccm) | | | | | | | | | | | | |
| Ar | 0 | 0 | 0 | 0 | 0 | 0 | 0 | 0 | 0 | 0 | 0 | 0 |
| (sccm) | | | | | | | | | | | | |
| O₂ | 0 | 10 | 96 | 0 | 10 | 96 | 0 | 10 | 96 | 0 | 10 | 96 |
| (sccm) | | | | | | | | | | | | |
| RF Power | 500 | 500 | 100 | 500 | 500 | 100 | 500 | 500 | 100 | 500 | 500 | 100 |
| (W) | | | | | | | | | | | | |

The results for residue, photospeed, etch voids, and surface roughness after etching are shown in Table 5.

TABLE 5

| | | E₀ | Voids | Surface roughness |
|---|---|---|---|---|
| Example | Residue | (mJ/cm²) | after etching | after etching |
| 1* | No | 50 | C | C |
| 2* | Yes | NA | B | B |
| 3* | No | 5 | D | D |
| 4* | Yes | 7 | C | C |
| 5* | No | 64 | D | C |
| 6 | No | 40 | A | A |
| 7 | No | 69 | A | A |
| 8 | No | 35 | A | B |
| 9 | No | 34 | A | A |
| 10 | No | 33 | A | A |
| 11 | No | 14 | A | C |

*denotes comparative example

In Table 5, the voids after etching and surface roughness after etching are scored using the following qualitative terms: A is the best performance; B is acceptable performance; C is deficient performance; and D is unacceptable performance. As shown in Table 5, the inventive photoresist compositions of Examples 6 to 11 were completely removed with no residue by development with TMAH of the exposed area after post exposure bake, and achieved reduced etch voids and improved surface roughness as compared to the photoresist compositions of Examples 1 to 5.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A polymer comprising:
a first repeating unit derived from a monomer comprising a hydroxy-aryl group;
a second repeating unit derived from a monomer comprising a hydroxy-aryl group protected with an acetal or ketal group;
a third repeating unit derived from a (meth)acrylate monomer comprising a cycloaliphatic group; and
a fourth repeating unit derived from a monomer comprising an acid-sensitive group,
wherein the first repeating unit, the second repeating unit, the third repeating unit, and the fourth repeating unit are different from each other.

2. The polymer of claim 1, wherein
the first repeating unit is derived from a monomer of formula (1);
the second repeating unit is derived from a monomer of formula (2);
the third repeating unit is derived from a monomer of formula (3); and
the fourth repeating unit is derived from a monomer of formula (4a) or (4b): 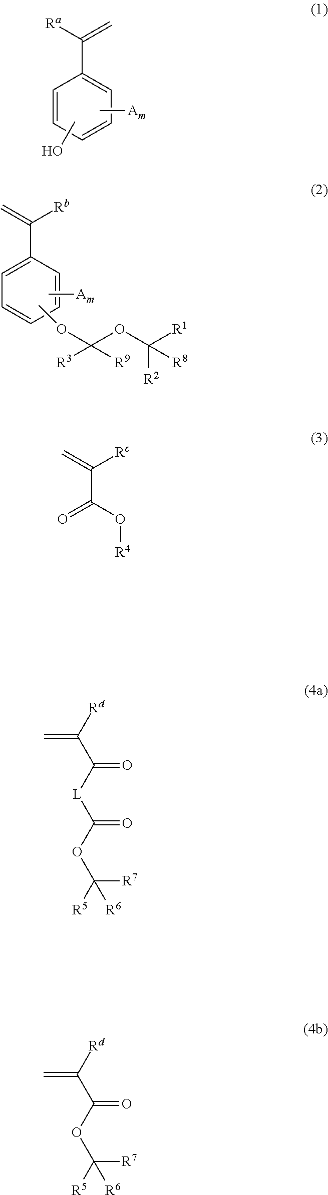
wherein, in formulae (1), (2), (3), (4a), and (4b),
R^{a}, R^{b}, R^{c}, and R^{d} are each independently hydrogen, fluorine, a substituted or unsubstituted C₁₋₅ alkyl, or a substituted or unsubstituted C₁₋₅ fluoroalkyl;
R¹, R², and R⁸ are each independently hydrogen, a straight chain or branched C₁₋₂₀ alkyl, a straight chain or branched C₁₋₂₀ heteroalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted; and optionally, any two of R′, R², and R⁸ together form a monocyclic ring or R², and R⁸ together form a polycyclic ring;
R³ is a substituted or unsubstituted straight chain or branched C₁₋₂₀ alkyl, a substituted or unsubstituted monocyclic or polycyclic C₃₋₂₀ cycloalkyl, a substituted or unsubstituted monocyclic or polycyclic C₃₋₂₀ heterocycloalkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ heteroalkyl;
R⁴ is a monocyclic or polycyclic C₃₋₃₀ cycloalkyl, or a monocyclic or polycyclic C₃₋₃₀ heterocycloalkyl, each of which is unsubstituted or substituted, provided that R⁴ does not include a tertiary carbon atom directly bonded to the divalent oxygen atom of the carboxylate group;
R⁹ is hydrogen, a substituted or unsubstituted straight chain or branched C₁₋₂₀ alkyl, a substituted or unsubstituted monocyclic or polycyclic C₃₋₂₀ cycloalkyl, a substituted or unsubstituted monocyclic or polycyclic C₃₋₂₀ heterocycloalkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ heteroalkyl;
optionally, one of R¹, R², or R⁸ and one of R³ or R⁹ together form a ring;
L is a linking unit comprising at least one carbon atom and at least one heteroatom;
R⁵, R⁶, and R⁷ are each independently a straight chain or branched C₁₋₂₀ alkyl, a monocyclic or polycyclic C₃₋₂₀ cycloalkyl, a monocyclic or polycyclic C₃₋₂₀ heterocycloalkyl, a straight chain or branched C₂₋₂₀ alkenyl, a monocyclic or polycyclic C₃₋₂₀ cycloalkenyl, a monocyclic or polycyclic C₃₋₂₀ heterocycloalkenyl, a monocyclic or polycyclic C₆₋₂₀ aryl, or a monocyclic or polycyclic C₄₋₂₀ heteroaryl, each of which is substituted or unsubstituted, and any two of R⁵, R⁶, and R⁷ together optionally form a ring;
each A is independently a halogen, a hydroxy, a carboxylic acid or ester, a thiol, a straight chain or branched C₁₋₂₀ alkyl, a monocyclic or polycyclic C₃₋₂₀ cycloalkyl, a monocyclic or polycyclic C₃₋₂₀ fluorocycloalkenyl, a monocyclic or polycyclic C₃₋₂₀ heterocycloalkyl, a monocyclic or polycyclic C₆₋₂₀ aryl, or a monocyclic or polycyclic C₄₋₂₀ heteroaryl, each of which is substituted or unsubstituted; and
each m is independently an integer of 0 to 4.

3. The polymer of claim 1, wherein
the first repeating unit is derived from a monomer of formula (1a); 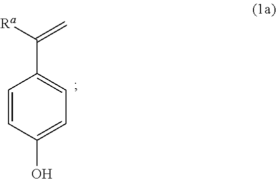
and
the second repeating unit is derived from a monomer of formula (2a); 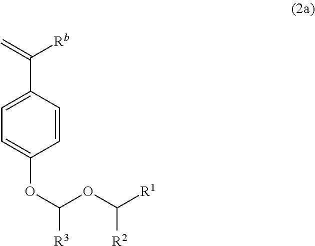
wherein, in formulae (1a) and (2a),
R^{a} and R^{b} are each independently hydrogen, fluorine, a substituted or unsubstituted C₁₋₅ alkyl, or a substituted or unsubstituted C₁₋₅ fluoroalkyl;
R¹ and R² are each independently hydrogen, a straight chain or branched C₁₋₂₀ alkyl, a straight chain or branched C₁₋₂₀ heteroalkyl, a monocyclic or polycyclic C₃₋₂₀ cycloalkyl, a monocyclic or polycyclic C₃₋₂₀ heterocycloalkyl, a monocyclic or polycyclic C₆₋₂₀ aryl, a C₇₋₂₀ aryloxyalkyl, or a monocyclic or polycyclic C₄₋₂₀ heteroaryl, each of which is substituted or unsubstituted, provided that both R¹ and R² are not hydrogen; and optionally, R¹ and R² together form a ring; and
R³ is a substituted or unsubstituted C₁₋₁₂ alkyl, a substituted or unsubstituted C₆₋₁₄ aryl, a substituted or unsubstituted C₃₋₁₄ heteroaryl, a substituted or unsubstituted C₇₋₁₈ arylalkyl, a substituted or unsubstituted C₄₋₁₈ heteroarylalkyl, or a substituted or unsubstituted C₁₋₁₂ heteroalkyl; and optionally, R³ and one of R¹ or R² together form a ring.

4. The polymer of claim 1, comprising:
45 to 70 mole percent of the first repeating unit;
5 to 45 mole percent of the second repeating unit;
3 to 40 mole percent of the third repeating unit; and
5 to 30 mole percent of the fourth repeating unit,
each based on 100 mole percent of total repeating units in the polymer.

5. A photoresist composition, comprising:
the polymer of claim 1;
a photoacid generator; and
a solvent.

6. The photoresist composition of claim 5, further comprising a second polymer that is different from the polymer of claim 5, wherein the second polymer is capable of switching solubility from insoluble to soluble in a 0.26 N TMAH aqueous solution upon reaction with acid.

7. The photoresist composition of claim 5, further comprising a plasticizer.

8. A method of forming a pattern, the method comprising:
applying a layer of the photoresist composition of claim 5 on a substrate;
drying the applied photoresist composition to form a photoresist composition layer;
exposing the photoresist composition layer to activating radiation;
heating the exposed photoresist composition layer; and
developing the exposed composition layer to form a resist pattern.

9. The method of claim 8, wherein the layer of the photoresist composition layer has a thickness of at least 5 micrometers.

10. The method of claim 8, further comprising forming a staircase pattern in the substrate using the photoresist composition layer as an etch mask, wherein the staircase pattern comprises a plurality of stairs.
